(19) United States
(12) Patent Application Publication
(10) Pub. No.: US 2004/0083419 A1
(43) Pub. Date: Apr. 29, 2004

(54) Detection circuit and decoding circuit

(75) Inventors: Osamu Chiba, Tokyo (JP); Yoshifumi Azekawa, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/431,459

(22) Filed: May 8, 2003

(30) Foreign Application Priority Data
Oct. 24, 2002 (JP) 2002-309303

(51) Int. Cl. H03M 13/00; H04L 1/00; G06F 11/00; G08C 25/00

(52) U.S. Cl. 714/799

(57) ABSTRACT

A disparity signal and a 6-bit subblock are provided to a 5B/6B decoding part, and a decoded data, a disparity signal, and an error candidate signal are outputted from the 5B/6B decoding part. The disparity signal and a 4-bit subblock are provided to a 3B/4B decoding part, and a decoded data, a disparity signal, and an error candidate signal are outputted from the 3B/4B decoding part. A data hold circuit delays the disparity signal by one clock and then provides the resulting signal to the 5B/6B decoding part. At least part of the decoding processing in the 3B/4B decoding part is executed in parallel with the obtaining of the disparity signal in the 5B/6B decoding part.

### BACKGROUND OF THE INVENTION

1. Field of the Invention

The present invention relates to a technique of decoding signals transmitted in high-speed cable network communication and, in particular, to a technique of decoding signals transmitted in block-coded DC balanced data. These can be employed as for example a decoding technique in 8B/10B encoding technique.

2. Description of the Background Art

In connection with the 8B/10B encoding technique, a technique of simplifying a circuit for verifying running disparity is presented in Japanese Patent Application Laid-Open No. 5-284037, and a technique of disposing two encoders implementing 8B/10B encoding is presented in Japanese Patent Application Laid-Open No. 2001-511323.

Decoding in the 8B/10B encoding technique is to decode 5-bit and 3-bit data from a 6-bit subblock and a 4-bit subblock, respectively, which constitute a code group. Decoding from either subblock requires a running disparity available from a subblock just prior to that subblock.

### SUMMARY OF THE INVENTION

It is an object of the present invention to provide a technique of quickly executing decoding in units of code groups.

A detection circuit of the present invention detects invalidness of a code group composed of first and second subblocks. The detection circuit has first and second processing parts. The first processing part obtains a first running disparity about the first subblock. The second processing part obtains a second running disparity about the second subblock, based on the first running disparity. At least part of the operation for obtaining the second running disparity is performed in parallel with the operation of obtaining the first running disparity.

It is quickly detectable whether the code group is invalid or not.

A decoding circuit of the present invention decodes a code group composed of first and second subblocks. The decoding circuit has first and second decoding parts. The first decoding part obtains a first running disparity and a first decoded data about the first subblock. The second decoding part obtains a second running disparity and a second decoded data about the second subblock, based on the first running disparity. At least part of the operation of obtaining the second decoded data is performed in parallel with the operation of obtaining the first running disparity.

The code group decoding can be executed quickly.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the configuration according to a basic idea of the present invention;

FIG. 2 is a block diagram showing the configuration of a first preferred embodiment of the present invention;

FIG. 3 is a block diagram showing the configuration of a second preferred embodiment of the present invention;

FIG. 4 is a block diagram showing the configuration of a third preferred embodiment of the present invention;

FIG. 5 is a block diagram showing the configuration of a fourth preferred embodiment of the present invention;

FIGS. 6 and 7 are program lists showing part of the functions in the fourth preferred embodiment;

FIGS. 8 and 9 are block diagrams showing part of the configuration of the fourth preferred embodiment;

FIG. 10 is a block diagram showing the configuration of a fifth preferred embodiment of the present invention;

FIG. 11 is a block diagram showing the configuration of a sixth preferred embodiment of the present invention; and

FIGS. 12 and 13 are block diagrams showing modified configurations according to the present invention.

### DESCRIPTION OF THE PREFERRED EMBODIMENTS

All of the following 8B/10B encoding techniques will be described in accordance with the definition in IEEE802.3clause36. However, it is to be understood that the followings are cited merely by way of example and the present invention is not limited to the cases in accordance with the above-mentioned definition.

### Basic Idea of the Present Invention

A description of the basic idea of the present invention will be presented prior to the description of concrete preferred embodiments of the present invention. This basic idea is also the concept capable of constituting the present invention.

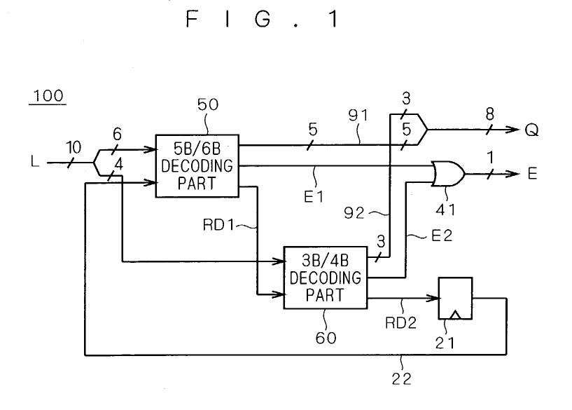

FIG. 1 is a block diagram showing the configuration of a decoding circuit 100 in the 8B/10B encoding technique. The decoding circuit 100 converts a 10-bit code group L to an 8-bit decoded data Q. The code group L consists of a 6-bit subblock and a 4-bit subblock that are represented by “abcdei” and “fghj”, respectively. The decoded data Q consists of a 5-bit decoded data 91 and a 3-bit decoded data 92 that are represented by “EDCBA” and “HGF”, respectively.

The decoding circuit 100 has a 5B/6B decoding part 50, a 3B/4B decoding part 60, and a data hold circuit 21. A disparity signal 22 indicating the positive or negative of the running disparity of a code group L and a subblock “abcdei” are inputted to the 5B/6B decoding part 50. The 5B/6B decoding part 50 outputs a 5-bit decoded data 91 (“EDCBA”), a disparity signal RD1, and an error candidate signal E1. The disparity signal RD1 indicates the positive or negative of the running disparity of a 6-bit subblock that is available from the subblock “abcdei.” The disparity signal RD1 takes “1” and “0” in accordance with the positive and negative of the running disparity of the 6-bit subblock, respectively. The error candidate signal E1 takes “0” when the subblock “abcdei” has a value obtainable in the normal operation, and it takes “1” for other values. In other words, the error candidate signal E1 is activated when the 6-bit subblock has a value that is not obtainable in the normal operation.

A disparity signal RD1 and a subblock “fghj” are inputted to the 3B/4B decoding part 60. The 3B/4B decoding part 60 outputs a 3-bit decoded data 92 (“HGF”), a disparity signal RD2, and an error candidate signal E2. The disparity signal RD2 indicates the positive or negative of the running disparity of the 4-bit subblock that is available from the subblock “fghj.” The disparity signal RD2 takes “1” and “0” in accordance with the positive and negative of the running disparity of the 4-bit subblock, respectively. The error candidate signal E2 takes “0” when the subblock “fghj” has a value that is obtainable in the normal operation, and it takes “1” for other values. In other words, the error candidate signal E2 is activated when the 4-bit subblock takes a value that is not obtainable in the normal operation.

The disparity signal RD2 is applied to the data hold circuit 21. Based on a clock signal (not shown), the data hold circuit 21 delays the disparity signal RD2 by one clock and then outputs the resulting signal as a disparity signal 22. Therefore, a single decoded data Q per clock is obtainable by applying a single code group L per clock to the decoding circuit 100.

When at least one of the error candidate signals E1 and E2 or each of them takes “1”, the error signal E takes “1” by a logic gate 41 that executes an OR between the two. That is, the error signal E indicates as to whether the obtained decoded data Q is invalid or not by “1” and “0”, respectively. The error signal E is activated when at least one of the 6-bit subblock and 4-bit subblock has a value obtainable in the normal operation.

To decode a single code group L per clock requires the decoding processing by the 5B/6B decoding part 50 and that by the 3B/4B decoding part 60 to be executed within one clock. To meet this requirement, it can be considered to perform these decoding processings by using look-up tables without employing any mathematical solution. Even so, however, the decoding processing by the 3B/4B decoding part 60 requires the disparity signal RD1 available from the 5B/6B decoding part 50.

The following preferred embodiments present such a technique that at least part of the decoding processing in 3B/4B decoding is executed in parallel with the obtaining of the disparity signal RD1 in 5B/6B decoding.

### First Preferred Embodiment

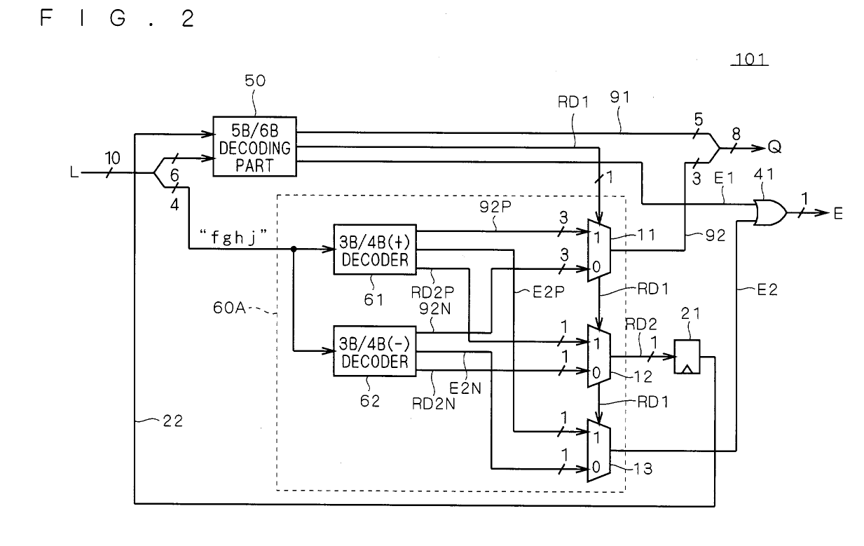

FIG. 2 is a block diagram showing the configuration of a decoding circuit 101 according to a first preferred embodiment of the present invention. The decoding circuit 101 also decodes the above-mentioned code group L and obtains the decoded data Q.

The decoding circuit 101 is different from the decoding circuit 100 in that the 3B/4B decoding part 60 is replaced with a 3B/4B decoding part 60A. The 3B/4B decoding part 60A has a 3B/4B (+) decoder 61, a 3B/4B (−) decoder 62, and selectors 11, 12, and 13.

A 4-bit subblock “fghj” is inputted to the 3B/4B (+) decoder 61 and 3B/4B (−) decoder 62. A disparity signal RD1 is applied to the selectors 11 and 12.

As provided for in Table36 of 2000Edition of IEEE802.3, as in 5B/6B decoding (the conversion from “abcdei” to “EDCBA”), conversion tables in units of the polarities of current running disparity are prepared in 3B/4B decoding (the conversion from “fghj” to “HGF”).

Table 1 illustrates the association of 3B/4B, which is formally an encoding table but substantially usable as a decoding table. The left, middle, and right columns of Table 1 express, in row-by-row matching fashion, 3-bit decoded data “HGF subblock, subblocks “fghj” corresponding to the decoded data “HGF” when current running disparity (i.e., the running disparity about a 6-bit subblock) is negative, and subblock “fghj” corresponding to the decoded data “HGF” when the current running disparity is positive, respectively. In a look-up table used for decoding, decoded data are set per subblock “fghj”, and the individual decoded data consist of 2⁴ entries covering the positive and negative current disparity cases.

TABLE 1
3B/4B coding for Data Characters

| Unencoded | Current RD− | Current RD+ |
|---|---|---|
| HGF | fghj | fghj |
| --.0: 000 | 1011 | 0100 |
| --.1: 001 | 1001 | 1001 |
| --.2: 010 | 0101 | 0101 |
| --.3: 011 | 1100 | 0011 |
| --.4: 100 | 1101 | 0010 |
| --.5: 101 | 1010 | 1010 |
| --.6: 110 | 0110 | 0110 |
| --.7: 111 | 1110 | 0001 |
| | (0111) | (1000) |

With respect to the subblock “fghj” and the polarity of current running disparity, a single decoded data “HGF” is determined without depending on the value of a subblock “abcdei” itself. For example, when the polarity of current running disparity is negative and a subbock “fghj” is “1011”, the corresponding decoded data “HGF” is “000”. This does not mean that depending on the polarity of current running disparity, there are two decoded data “HGF” corresponding to a single subblock “fghj”.

The 3B/4B (+) decoder 61 and 3B/4B (−) decoder 62 have look-up tables corresponding to the positive and negative in the current running disparity about 3B/4B decoding (equivalent to the running disparity about a 6-bit subblock). That is, the 3B/4B (+) decoder 61 has a look-up table that associates the contents of the right and left columns in Table 1, and the 3B/4B (−) decoder 62 has a look-up table that associates the contents of the middle and left columns in Table 1. Based on these look-up tables and subblock “fghj”, the 3B/4B (+) decoder 61 and 3B/4B (−) decoder 62 output decoded data candidates 92P and 92N, respectively, which are candidates of the decoded data 92. When the value of an inputted subblock “fghj” does not exist in the corresponding look-up tables, the decoders 61 and 62 output spare error candidate signals E2P and E2N, respectively, which are candidates of the error candidate signal E2. The 3B/4B (+) decoder 61 and 3B/4B (−) decoder 62 have also the function of obtaining a new running disparity based on the current running disparity and subblock “fghj”, and output disparity candidate signals RD2P and RD2N, respectively, indicating whether the candidate of running disparity of a 4-bit subblock is positive or negative. These operations of the decoders 61 and 62 are executed in parallel with the operation of the 5B/6B decoding part 50.

The decoded data candidates 92P and 92N are inputted to one input terminal of the selector 11 (designated by the reference character 1 in the drawing) and the other input terminal (designated by the reference character 0 in the drawing), respectively. The disparity candidate signals RD2P and RD2N are inputted to one input terminal of the selector 12 (designated by the reference character 1 in the drawing) and the other input terminal (designated by the reference character 0 in the drawing), respectively. The spare error candidate signals EN2P and EN2N are inputted to one input terminal of the selector 13 (designated by the reference character 1 in the drawing) and the other input terminal (designated by the reference character 0 in the drawing), respectively When the running disparity of a 6-bit subblock is positive, the disparity signal RD1 is “1”. Then, the selector 11 outputs the decoded data candidate 92P as decoded data 92, the selector 12 outputs the disparity candidate signal RD2P as a disparity signal PD2, and the selector 13 outputs the spare error candidate signal E2P as an error candidate signal E2.

When the running disparity of the 6-bit subblock is negative, the disparity signal RD1 is “0”. Then, the selector 11 outputs the decoded data candidate 92N as decoded data 92, the selector 12 outputs the disparity candidate signal RD2N as a disparity signal PD2, and the selector 13 outputs the spare error candidate signal E2N as an error candidate signal E2.

Thus, the 3B/4B decoding part 60A obtains the decoded data candidates 92P, 92N, disparity candidate signals RD2P, RD2N, and spare error candidate signals E2P, E2N before obtaining a disparity signal RD1. After the disparity signal RD1 is obtained, the selector 11 selects the decoded data 92 from the decoded data candidates 92P and 92N, the selector 12 selects the disparity signal RD2 from the disparity candidates RD2P and RD2N, and the selector 13 selects the error candidate signal E2 from the spare error candidate signals E2P and E2N. Thus, at least part of the 4-bit subblock decoding, i.e., the processing for obtaining a pair of decoded data candidates, either of which is selected as decoded data, is executed in parallel with the processing for obtaining the running disparity of the 6-bit subblock. This permits a quick decoding per code group.

In general, the decoding processing of 3B/4B has less bit number of data as the object of conversion than the decoding processing of 5B/6B, and therefore, the operation speed of the former is faster than that of the latter. Especially, the processing that the 3B/4B (+) decoder 61 obtains the decoded data candidate 92P, disparity candidate signal RD2P, and spare error candidate signal E2P can be performed in parallel with the processing that the 3B/4B (−) decoder 62 obtains the decoded data candidate 92N, disparity candidate signal RD2N, and spare error candidate signal E2N. In this instance, the 3B/4B (+) decoder 61 and 3B/4B (−) decoder 62 are configured to store the look-up table for the case where the running disparity of the 6-bit subblock is positive and the look-up table for the case where it is negative, respectively. Therefore, these look-up tables have a size one-half the size of a look-up table to be used for the search based on the data RD1 and 4-bit subblock “fghj”, so that the processing itself of the 3B/4B (+) decoder 61 and 3B/4B (−) decoder 62 is quick. It is easy to input the decoded data candidates 92P and 92N, disparity candidate signals RD2P and RD2N, and spare error candidate signals E2P and E2N to the selectors 11, 12, and 13, respectively, before the selection operation of the selectors 11 and 12 are valid.

### Second Preferred Embodiment

A second preferred embodiment of the invention presents a technique of increasing the operation speed of the 5B/6B decoding part 50, thereby increasing the operation speed of the decoding circuit 101.

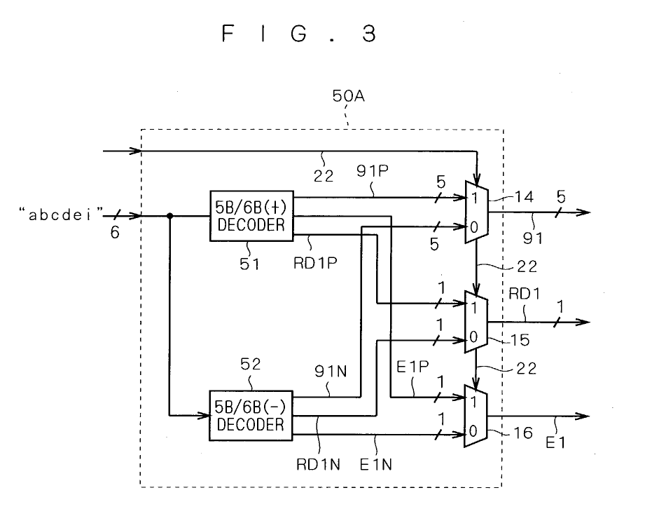

FIG. 3 is a block diagram showing the configuration of a 5B/6B decoding part 50A that is usable as the 5B/6B decoding part 50 of the decoding circuit 101. The 5B/6B decoding part 50A has a 5B/6B (+) decoder 51, a 5B/6B (−) decoder 52, and selectors 14, 15, and 16.

A 6-bit subblock “abcdei” is inputted to the 5B/6B (+) decoder 51 and 5B/6B (−) decoder 52. A disparity signal 22 is applied to the selectors 14 and 15. As shown in FIG. 1, the subblock “abcdei” is obtainable from the code group L inputted to the decoding circuit 101, and the disparity signal 22 is obtainable from the data hold circuit 21.

As provided for in Table36 of 2000Edition of IEEE802.3, a conversion table is prepared by polarity of current running disparity in 5B/6B decoding (the conversion from “abcdei” to “EDCBA”).

Table 2 illustrates the association of 5B/6B, which is formally an encoding table but substantially usable as a decoding table. The left, middle, and right columns of Table 2 express, in row-by-row matching fashion, 5-bit decoded data “EDCBA”, subblock “abcdei” corresponding to the decoded data “EDCBA” when the current running disparity is negative, and subblock “abcdei” corresponding to the decoded data “EDCBA” when the current running disparity is positive, respectively. In a look-up table used for decoding, decoded data are set per subblock “abcdei”, and the individual data consists of 2⁶ entries covering the positive and negative current disparity cases.

TABLE 2
5B/6B coding for Data Characters

| Unencoded | Current RD− | Current RD+ |
|---|---|---|
| EDCBA | abcdei | abcdei |
| D0:00000 | 100111 | 011000 |
| D1:00001 | 011101 | 100010 |
| D2:00010 | 101101 | 010010 |
| D3:00011 | 110001 | 110001 |
| D4:00100 | 110101 | 001010 |
| D5:00101 | 101001 | 101001 |
| D6:00110 | 011001 | 011001 |
| D7:00111 | 111000 | 000111 |
| D8:01000 | 111001 | 000110 |
| D9:01001 | 100101 | 100101 |
| D10:01010 | 010101 | 010101 |
| D11:01011 | 110100 | 110100 |
| D12:01100 | 001101 | 001101 |
| D13:01101 | 101100 | 101100 |
| D14:01110 | 011100 | 011100 |
| D15:01111 | 010111 | 101000 |
| D16:10000 | 011011 | 100100 |
| D17:10001 | 100011 | 100011 |
| D18:10010 | 010011 | 010011 |
| D19:10011 | 110010 | 110010 |
| D20:10100 | 001011 | 001011 |
| D21:10101 | 101010 | 101010 |
| D22:10110 | 011010 | 011010 |
| D23:10111 | 111010 | 000101 |
| D24:11000 | 110011 | 001100 |
| D25:11001 | 100110 | 100110 |
| D26:11010 | 010110 | 010110 |
| D27:11011 | 110110 | 001001 |
| D28:11100 | 001110 | 001110 |
| D29:11101 | 101110 | 010001 |
| D30:11110 | 011110 | 100001 |
| D31:11111 | 101011 | 010100 |

Basically, a single decoded data “EDCBA” is determined with respect to a subblock “abcdei” and the polarity of running disparity, without depending on the value of a subblock “fghj” itself. For example, when the polarity of running disparity is negative and the subblock “abcdei” is “100111”, the corresponding decoded data “EDCBA” is “00000”. This does not mean that there are two decoded data “EDCBA” corresponding to a single subblock “abcdei”, depending on the polarity of running disparity.

The 5B/6B (+) decoder 51 and 5B/6B (−) decoder 52 have look-up tables corresponding to the positive and negative of the current running disparity about 5B/6B decoding (equivalent to the running disparity about the code group L). That is, the 5B/6B (+) decoder 51 has a look-up table that associates the contents of the right and left columns in Table 2, and the 5B/6B (−) decoder 52 has a look-up table that associates the contents of the middle and left columns in Table 2. Based on these look-up tables and subblock “abcdei”, the 5B/6B (+) decoder 51 and 5B/6B (−) decoder 52 output decoded data candidates 91P and 91N, respectively, which are candidates of the decoded data 91. When the value of an inputted subblock “abcdei” does not exist in the individual look-up tables, the decoders 51 and 52 output spare error candidate signals E1P and E1N, respectively, which are candidates of the error candidate signal E1. The 5B/6B (+) decoder 51 and 5B/6B (−) decoder 52 have also the function of obtaining a new running disparity based on a current running disparity and subblock “abcdei”, and output disparity candidate signals RD1P and RD1N, respectively, which are candidates of the disparity signal RD1. These operations of the decoders 51 and 52 are executed in parallel.

The decoded data candidate 91P is inputted to one input terminal of the selector 14 (designated by the reference character 1 in the drawing) and the decoded data candidate 91N is inputted to the other input terminal of the selector 14 (designated by the reference character 0 in the drawing). The disparity candidate signals RD1 is inputted to one input terminal of the selector 15 (designated by the reference character 1 in the drawing) and the disparity candidate signal RD1N is inputted to the other input terminal of the selector 15 (designated by the reference character 0 in the drawing). When the running disparity about the code group L is positive, the disparity signal RD1 is “1”. Then, the selector 14 outputs the decoded data candidate 92P as decoded data 92, the selector 15 outputs the disparity candidate signal RD2P as a disparity signal PD2, and the selector 16 outputs the spare error candidate signal E1P as an error candidate signal E1.

When the running disparity about the code group L is negative, the disparity signal RD1 is “0”. Then, the selector 14 outputs the decoded data candidate 92N as decoded data 92, the selector 15 outputs the disparity candidate signal RD2N as a disparity signal PD2, and the selector 16 outputs the spare error candidate signal E1N as an error candidate signal E1.

Thus, like the processing in the 3B/4B decoding part 60, the processing that the 5B/6B (+) decoder 51 obtains the decoded data candidate 91P, disparity candidate signal RD1P, and spare error candidate signal E1P can be performed in parallel with the processing that the 5B/6B (−) decoder 52 obtains the decoded data candidate 91N, disparity candidate signal RD1N, and spare error candidate signal E1N. The look-up tables used at that time by the 5B/6B (+) decoder 51 and 5B/6B (−) decoder 52 are composed so as to share the case where the running disparity about the code group L is positive and the case where that is negative. Therefore, these look-up tables have a size of one-half the size of a look-up table to be used for the search based on the data 22 and 6-bit subblock “abcdei”, so that the processing itself of the 5B/6B (+) decoder 51 and 5B/6B (−) decoder 52 is quick. This increases the operation speed of the 5B/6B decoding part 50A, thereby increasing the operation speed of the decoding circuit 101.

### Third Preferred Embodiment

Table36-1a of 2000Edition of IEEE802.3 defines the relationship between “HGF EDCBA” and “abcdei fghj” about data groups classified as a data code, wherein a name with acronym D is assigned to each code group. Tables 1 and 2 presented in the first and second preferred embodiments indicate the relationship between “HGF EDCBA” and “abcdei fghj” about data groups classified as a data code.

On the other hand, Table36-2 of 2000Edition of IEEE802.3 defines the relationship between “HGF EDCBA” and “abcdei fghj” about data groups classified as a special code, wherein a name with acronym K is assigned to each code group. The special code is control data about the start and termination of a packet. For example, a special code K30.7 indicates the presence of an error, and “HGF EDCBA” takes a value “111 11110”.

In code group names Dy.x and Ky,x, “x” and “y” are expressed as decimal notations of 3-bit decoded data and 5-bit decoded data, respectively.

Table 3 illustrates the relationship between “EDCBA” and “abcdei” about data groups classified as a special code. Table 4 indicates the relationship between “HGF” and “fghj” about data groups classified as a special code.

TABLE 3
5B/6B coding for Special Characters

| Unencoded | Current RD− | Current RD+ |
|---|---|---|
| EDCBA | Abcdei | abcdei |
| K28:11100 | 001111 | 110000 |
| D23:10111 | 111010 | 000101 |
| D27:11011 | 110110 | 001001 |
| D29:11101 | 101110 | 010001 |
| D30:11110 | 011110 | 100001 |

TABLE 4
3B/4B coding for Special Characters

| Unencoded | Current RD− | Current RD+ |
|---|---|---|
| HGF | Fghj | fghj |
| --.0: 000 | 1011 | 0100 |
| --.1: 001 | 0110 | 1001 |
| --.2: 010 | 1010 | 0101 |
| --.3: 011 | 1100 | 0011 |
| --.4: 100 | 1101 | 0010 |
| --.5: 101 | 0101 | 1010 |
| --.6: 110 | 1001 | 0110 |
| --.7: 111 | 0111 | 1000 |

In the first and second preferred embodiments, decoding of special codes is also possible if the contents of Table 4 and Table 3 are incorporated in Table 1 and Table 2, respectively.

However, as can be seen from Tables 3 and 4, the special codes have the following characteristic feature that a certain decoded data “HGF EDCBA” is obtained from a pair of code group L “abcdei fghj”, which are in a relation of inversion in each bit, depending on the polarity of current running disparity, and vice versa. For example, in a special code K30.7 that indicates an error and takes a value “111 11110”, from Table 3, a 6-bit subblock is set to “10000” and “011110” depending on the positive and negative of current running disparity, respectively, and from Table 4, a 4-bit subblock is set to “1000” and “0111” depending on the positive and negative of current running disparity, respectively. That is, the special code K30.7 is set to code groups “10000 0111” and “011110 1000” depending on the positive and negative of current running disparity, respectively. The former code group is obtained by inverting each bit of the latter code group, and vice versa.

Therefore, the special code decoding may be executed as follows. Employing look-up tables indicating only about either the positive or negative of the current running disparity in Tables 3 and 4, a code group to be inputted may be decoded directly or inverted and decoded, depending on the current running disparity. By doing so, the special code decoding can be performed quickly and the sizes of look-up tables required therefore can be reduced. In addition, even if the 5B/6B decoding part 50 and 3B/4B decoding part 60 have look-up tables only about data codes, special code decoding is possible on the decoding circuit as a whole.

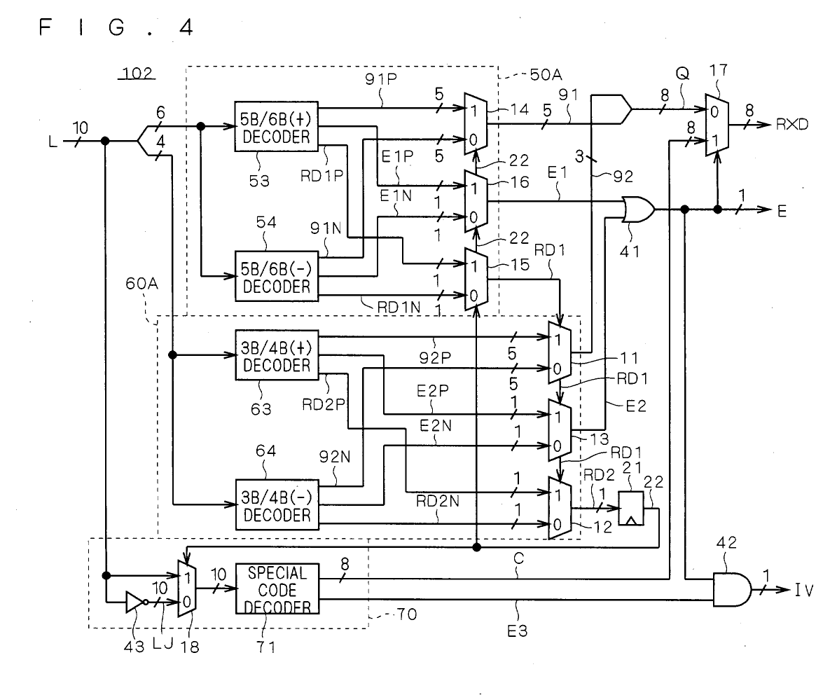

FIG. 4 is a block diagram showing the configuration of a decoding circuit 102 according to a third preferred embodiment of the present invention. The decoding circuit 102 is different from the decoding circuit 100 in that the 5B/6B decoding part 50A and 3B/4B decoding part 60A in the second and first preferred embodiments are employed in place of the 5B/6B decoding part 50 and 3B/4B decoding part 60, respectively, and that a special code decoding part 70, a selector 17, and a logic gate 42 are added.

In the third preferred embodiment, the 5B/6B decoding part 50A and 3B/4B decoding part 60A require no look-up tables about special codes. In order to discriminate from the 5B/6B (+) decoder 51, 5B/6B (−) decoder 52, 3B/4B (+) decoder 61, and 3B/4B (−) decoder 62, each requiring look-up tables in some cases, reference numerals 53, 54, 63, and 64 are used which correspond to these decoders in the order named. The error candidate signal E1 available from the 5B/6B decoding part 50A is activated when a 6-bit subblock takes a value that cannot be taken as a data code in the normal operation, and the error candidate signal E2 available from the 3B/4B decoding part 60A is activated when a 4-bit subblock takes a value that cannot be taken as a data code in the normal operation.

A decoded data Q is provided to one input terminal of the selector 17 (designated by the reference character 1 in the drawing). In the decoding circuit 102 of the third preferred embodiment, both of the 5B/6B decoding part 50A and 3B/4B decoding part 60A store look-up tables only about data codes. Therefore, the decoded data Q is also decoding results about the data codes. A decoded data C of special codes available from the special code decoding part 70 are provided to the other input terminal of the selector 17 (designated by the reference character 0 in the drawing).

When an error signal E is “0”, that is, a code group L takes a normal value as a data code, the decoding circuit 102 outputs the decoded data Q as a decoding result RDX. On the other hand, the fact that the error signal E is “1” indicates that the decoded data Q is invalid as a data code. In this case, the code group L is to be a special code, except for the case that the code group L is invalid and the case that the disparity signal 22 is invalid. Therefore, the decoding circuit 102 outputs the decoded data C as a decoding result RXD.

The special code decoding part 70 has a special code decoder 71, a selector 18, and a 10-bit inverter 43 outputting data LJ that is obtained by inverting each bit of the code group L (hereinafter referred to as an “inverted code group LJ”). The special code decoder 71 stores only positive current running disparity cases in Tables 3 and 4, as a look-up table. Therefore, when the current running disparity is positive, an 8-bit decoded data C is obtained from the code group L by using the look-up table stored in the special code decoder 71. On the other hand, when the current running disparity is negative, because of the above-mentioned characteristic feature in the encoding and decoding about the special codes, the 8-bit decoded data C is obtainable from the inverted code group LJ that is obtained from the inverter 43 by using the look-up table stored in the special code decoder 71.

Thus, the selector 18 effects the function of providing the special code decoder 71 with either one of the code group L and inverted code group LJ depending on the polarity of current running disparity. That is, the code group L is provided to one input terminal of the selector 18 (designated by the reference character 1 in the drawing), and the inverted code group LJ is provided to the other input terminal (designated by the reference character 0 in the drawing). When the current running disparity is positive, the disparity signal 22 is “1”. Then, the selector 18 provides the code group L to the special code decoder 71. On the other hand, when the current disparity is negative, the disparity signal 22 is “0”. Then, the selector 18 provides the inverted code group LJ to the special code decoder 71. The decoded data C so obtained is provided to the selector 17.

The decoding result RXD outputted from the selector 17 is significant when there is no invalidness in the code group L and disparity signal 22. In other words, when the code group L does not correspond to any data code or any special code, the value of the decoding result RXD is not significant. It is therefore desirable to also detect the case where the code group L that does not correspond to any special code. For the purpose of this, when a 10-bit data that is not present in Table 3 or 4 is inputted, the special code decoder 71 outputs “1” as an error candidate signal E3. When a 10-bit data present in Table 3 or 4 is inputted, the decoder 71 outputs “0” as an error candidate signal E3. That is, the error candidate signal E3 is activated when a special code is not encoded about either one of the code group L and inverted code group LJ that are selected based on the current running disparity.

The logic gate 42 executes an AND operation between the error signal E and error candidate signal E3, and then outputs the result as an invalid signal IV. Accordingly, when the error signal IV takes a value “1”, the decoding result RXD is incorrect as a data code or special code, and indicates that the code group L is invalid. On the contrary, when the error signal E takes “1”, it means that “the decoding result RXD is not any data code,” however, it does not indicate whether or not “the decoding result RXD is a special code.” The decoding result RXD and error signal E can be used as a data character and control character, respectively, which are for example in the form of XGMII (10 G medium independent interface).

In some cases, only the function of detecting invalidness of the code group L and disparity signal 22 is required. In this case, the function of obtaining the decoded data Q and C is unnecessary and there is no need of storing decoded data in the look-up tables, thereby reducing the sizes of the look-up tables. None of the selectors 11, 14, and 17 are required.

### Fourth Preferred Embodiment

A fourth preferred embodiment presents a technique of setting the error candidate signal E2 more strictly. Specially, the data code Dy.7 expressed at the lowermost row in Table 1 is handled more strictly. When the decoded data “HGF” takes a value “111”, the subblock “fghj” can take four kinds of values. Basically, the subblock “fghj” takes either one of “1110” and “0001”. However, in the following data codes D11.7, D13.7, D14.7, D17.7, D18.7, and D20.7, their corresponding decoded data “HGF” take a value “111” with the exception that the subblock “fghj” takes a value other than “1110” and “0001”. The data codes D11.7, D13.7, and D14.7 cause an exception when the current running disparity (i.e., the running disparity of a 6-bit subblock) is positive, and the data codes D17.7, D18.7, and D20.7 cause an exception when the current running disparity is negative. These exceptional cases are enclosed in parentheses in Table 1. Specifically, in the data codes D11.7, D13.7, and D14.7, the subblock “fghj” takes “1000” when the current running disparity is positive. In the data codes D17.7, D18.7, and D20.7, the subblock “fghj” takes “0111” when the current running disparity is negative.

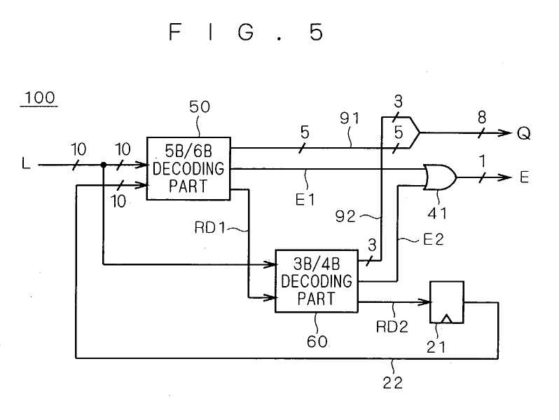

In order to also consider the above-mentioned exceptional cases, it is necessary to judge whether (i) when the current running disparity is positive, the subblock “abcdei” takes “110100”, “101100”, and “011100” corresponding to values 11, 13, and 14, respectively, and (ii) when the current running disparity is negative, the subblock “abcdei” takes “100011”, “010011”, and “001011” corresponding to values 17, 18, and 20, respectively. To make these judgments, it is desirable to input not only the subblock “fghj” but also the subblock “abcdei” to the 3B/4B decoding part 60. In this case, the decoding circuit 100 shown in FIG. 1 will be modified as shown in FIG. 5. The input provided to the 3B/4B (+) decoder 61 and 3B/4B (−) decoder 62, which are employed as a 3B/4B decoding part 60, is the code block L not the subblock “fghj”.

Making a reference to the subblock “abcdei” together with the subblock “fghj” by using the look-up tables is unfavorable because this reference increases the sizes of the look-up tables. It is therefore desirable to refer to the subblock “abcdei” only when the subblock “fghj” takes the above-mentioned exceptional value.

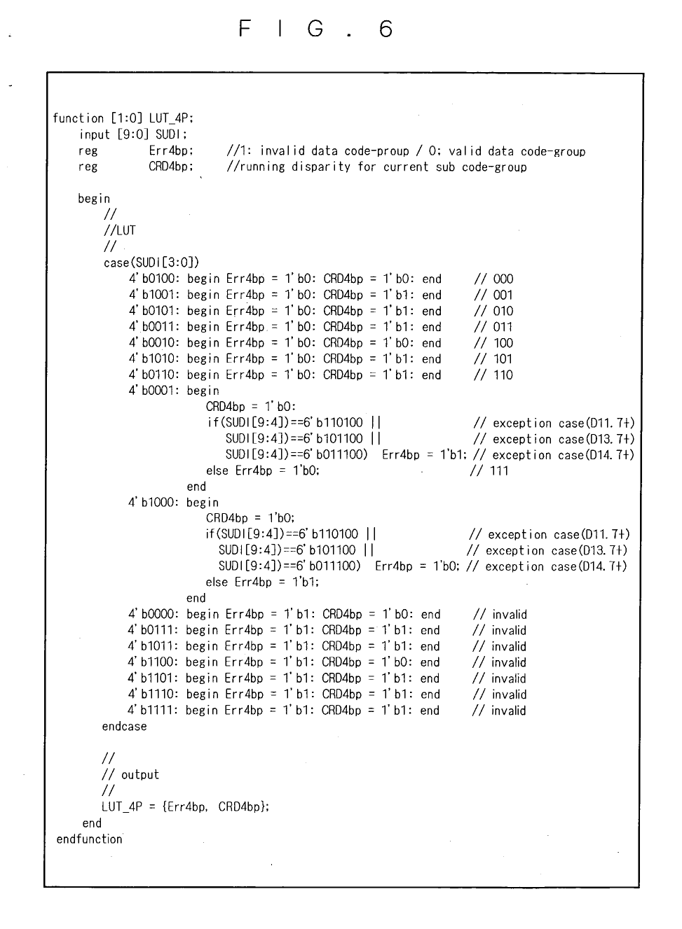

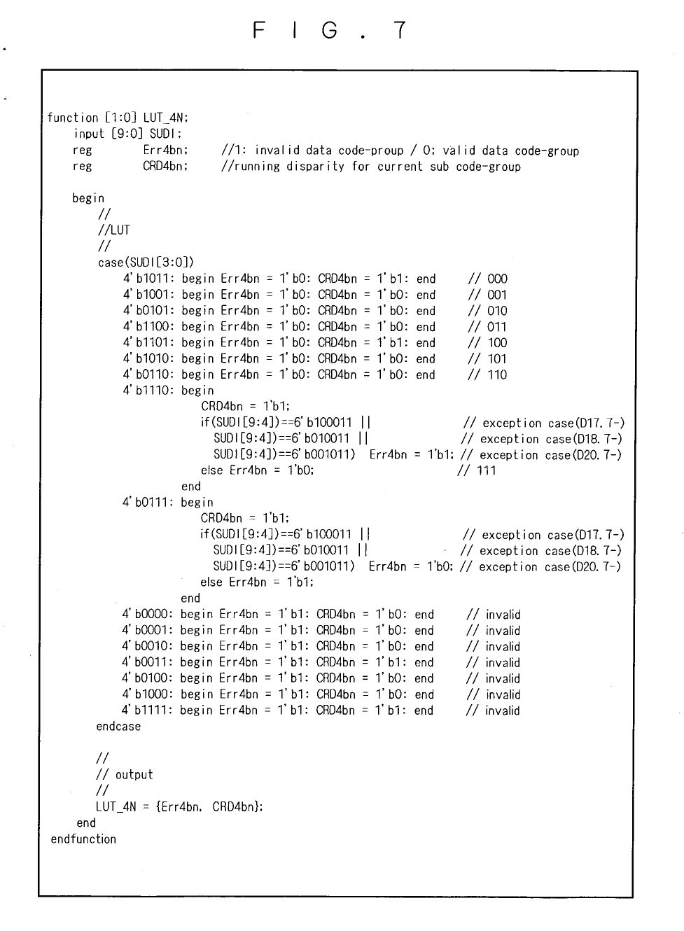

FIGS. 6 and 7 are program lists in which part of the functions of the 3B/4B (+) decoder 61 and 3B/4B (−) decoder 62 is expressed in Verilog (trademark)—HDL that is one of hardware description languages. Referring to these lists, register variables Err4bp and Err4bn correspond to the spare error candidate signals E2P and E2N in FIG. 2, respectively, register variables CRD4bp and CRD4bn correspond to the disparity candidate signals RD2P and RD2N in FIG. 2, respectively, and functions LUT_4P[1:0] and LUT_4N[1:0] are {Err4bp, CRD4bp} and {Err4bn, CRD4bn}, respectively. A 10-bit input pin SUDI corresponds to the code block L, and its lower order 4 bits [3:0] and its upper order 6 bits [9:4] correspond to the subblocks “fghj” and “abcdei”, respectively. In these program lists, the operation of data decoding is omitted.

The first to seventh conditional expressions in each case statement in these lists indicate the subblock “fghj” corresponding validly to the decoded data “HGF”. It should be noted that the case where the decoded data “HGF” takes “111” is eliminated from the seven conditional expressions. If these conditional expressions are satisfied, the register variables Err4bp and Err4bn are set to “0”.

The eighth and ninth conditional expressions in the list of FIG. 6 indicate the cases where the subblock “fghj” takes “0001” and “1000”, respectively. These conditional expressions indicate the corresponding subblock “fghj” when the running disparity of a 6-bit subblock “abcdei” is positive and the value of the decoded data “HGF” is “111”. In the eighth conditional expression in the list of FIG. 6, an error occurs only in data codes D11.7, D13.7, and D14.7. That is, the register variable Err4bp takes “1” when the input pin SUDI[9:4] corresponding to the subblock “abcdei” in an “if” statement is any one of “110100”, “101100”, and “011100”, whereas it takes “0” in other cases.

On the other hand, the ninth conditional expression indicates that only the cases of data codes D11.7, D13.7, and D14.7 are normal. This is because if the code group L is normal, the subblock “fghj” takes a value “1000” only when the code group L is the data code D11.7, D13.7, or D14.7. Therefore, in the “if” statement about this conditional expression, the register variable Err4bp takes “0” when the input pin SUDI[9:4] is any one of “110100”, “101100”, and “011100”, whereas it takes “1” in other cases.

Likewise, the eighth and ninth conditional expressions in the list of FIG. 7 indicate the cases that “fghj” takes “1110” and “0111”, respectively. In the eighth conditional expression, an error occurs in data codes D17.7, D18.7, and D20.7. That is, the register variable Err4bn takes “1” when the input pin SUDI[9:4] corresponding to the subblock “abcdei” in an “if” statement is any one of “100011”, “010011”, and “001011”, whereas it takes “0” in other cases.

On the other hand, the ninth conditional expression indicates that only data codes D17.7, D18.7, and D20.7 are normal. This is because if the code group L is normal, the subblock “fghj” takes a value “0111” only when the code group L is the data code D17.7, D18.7, or D20.7. Therefore, in the “if” statement about this conditional expression, the register variable Err4bp takes “0” when the input pin SUDI[9:4] is any one of “100011”, “010011”, and “001011”, whereas it takes “1” in other cases.

All of the next following seven conditional expressions in the individual lists (i.e., the 10th to 16th conditional expressions in the lists) indicate the subblock “fghj” not corresponding validly to the decoded data “HGF”. When any one of these conditional expressions is satisfied, the register variables Err4bp and Err4bn are set to “1”.

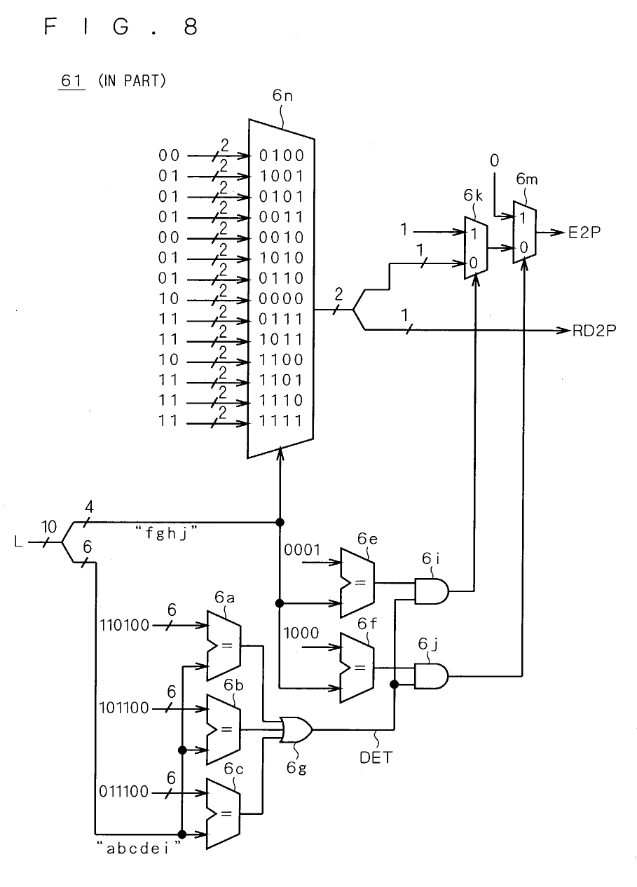

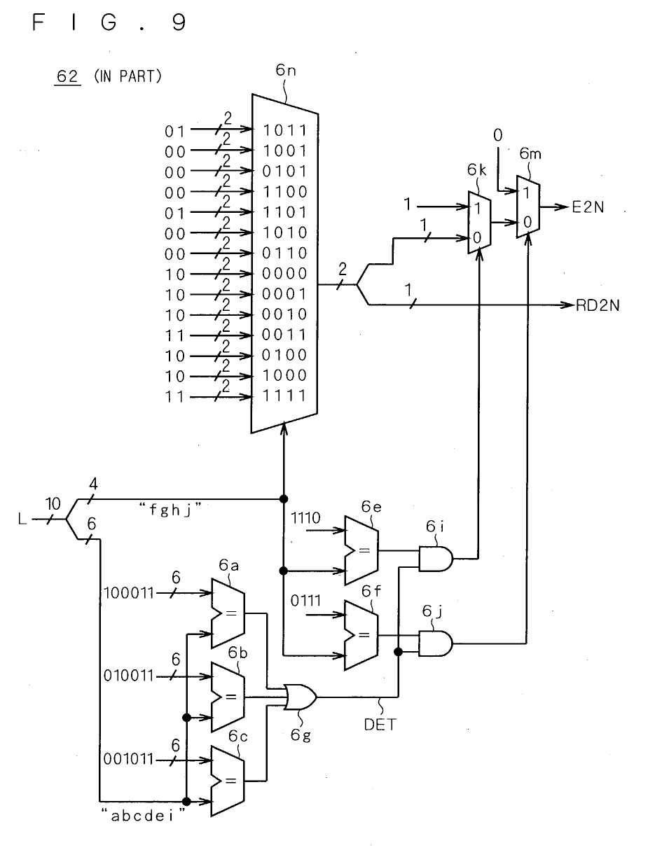

FIGS. 8 and 9 are block diagrams that illustrate part of the configurations of the 3B/4B (+) decoder 61 and 3B/4B (−) decoder 62, respectively (excluding the part for data decoding). These block diagrams correspond to the lists of FIGS. 6 and 7, respectively.

Both of the configurations shown in FIGS. 8 and 9 have 6-bit comparators 6a, 6b, and 6c, 4-bit comparators 6e and 6f, a 3-input OR gate 6g, 2-input AND gates 6i and 6j, 2-input selectors 6k and 6m, and a 14-input 1-output selector 6n.

Referring now to FIG. 8, the 3B/4B (+) decoder 61 will be described. The selector 6 n selectively outputs a single 2-bit data from 2-bit data that has been provided to 14 input terminals depending on the value of a subblock “fghj”. These 14 input terminals correspond to the first to seventh conditional expressions and 10th to 16th conditional expressions shown in FIG. 6, a 2-bit data to be inputted to the individual input terminals correspond to {Err4bp, CRD4bp}. Then, one bit equivalent to the variable Err4bp is inputted to the selector 6k. The value of one bit, “1”, is fixedly inputted to one input terminal of the selector 6k (designated by the reference character 1 in the drawing), and one bit equivalent to the variable Err4bp is inputted to the other input terminal of the selector 6k (designated by the reference character 0 in the drawing).

A value “0001” is inputted to one input terminal of the 4-bit comparator 6e, and the value of a subblock “fghj” is inputted to the other input terminal. If they agree, the comparator 6e outputs a value “1”. The operation of the comparator 6e corresponds to the eighth conditional expression in the list of FIG. 6. A value “1000” is inputted to one input terminal of the 4-bit comparator 6f, and the value of a subblock “fghj” is inputted to the other input terminal. If they agree, the comparator 6f outputs a value “1”. The operation of the comparator 6f corresponds to the ninth conditional expression in the list of FIG. 6.

A subblock “abcdei” is inputted to the respective input terminals of the comparators 6a, 6b, and 6c, and 6-bit values “110100”, “101100”, and “011100” are inputted to their respective other input terminals. The individual comparators 6a, 6b, and 6c output “1” when the 6-bit inputted to one input terminal agrees with the 6-bit inputted to the other input terminal, and output “0” when they do not agree. The OR gate 6g outputs the logical OR of these outputs as a signal DET. Accordingly, the case where the signal DET is “1” indicates that the subblock “fghj” takes normally a value “1000”. That is, the signal DET corresponds to the “if” statement in the ninth conditional expression in the list of FIG. 6.

The AND gate 6i executes a logical AND between the output of the comparator 6e and the signal DET, and outputs the result. If the output of the AND gate 6i is “1”, this is the case that the subblock “fghj” takes a value “0001” although it should normally be “1000”, and therefore the spare error candidate signal E2P should be “1”. If the output of the AND gate 6i is “0”, this is the case that “HGF” corresponding to the subblock “fghj” takes a value other than “111”. Therefore, determination of the value of the spare error candidate signal E2P is under control of the output of the selector 6n. The selector 6k executes this operation. That is, if the output of the AND gate 6i is “1”, the fixed input value “1” is outputted. If the output of the AND gate 6i is “0”, there is outputted one bit equivalent to the variable Err4bp among the outputs of the selector 6 n.

The AND gate 6j executes a logical AND between the output of the comparator 6f and the signal DET, and outputs the result. If the AND gate 6j takes a value “1”, this is the case where the subblock “fghj” should normally take a value “1000” and the subblock “fghj” takes a value “1000”. It is therefore judged that no error occurs. In this case, the selector 6m outputs a value “0” as the spare error candidate signal E2P. To achieve this operation of the selector 6m, the value of one bit, “0”, is fixedly provided to one input terminal of the selector 6m (designated by the reference character 1 in the drawing). On the other hand, if the output of the AND gate 6j takes a value “0”, this is a case other than that the subblock “fghj” normally takes a value “1000”. Therefore, the selector 6m employs the output of the selector 6k as the spare error candidate signal E2P.

The 3B/4B (−) decoder 62 shown in FIG. 9 is connected in approximately the same fashion as in the 3B/4B (+) decoder 61 shown in FIG. 8, and outputs a spare error candidate signal E2N and a disparity candidate signal RD2N. The 3B/4B (−) decoder 62 is different from the 3B/4B (+) decoder 61 in that (i) values “100011”, “010011”, and “001011” are provided to the one input terminals of the comparators 6a, 6b, and 6c, respectively; (ii) values “1110” and “0111” are provided to the one input terminals of the comparators 6e and 6f, respectively; and (iii) the value of a 4-bit corresponding to the input terminal of the selector 6n and the value of a 2-bit provided to these input terminals.

Thus, in the fourth preferred embodiment, it is judged whether such a value that the subblock “fghj” takes exceptionally is invalid or not by taking the subblock “abcdei” into consideration. This permits more strict judgment as to whether the code group L is invalid or not. Further, since in this judgment the subblock “abcdei” is referred to only when the subblock “fghj” takes the above-mentioned exceptional value, it is unnecessary to greatly increase the sizes of the look-up tables.

### Fifth Preferred Embodiment

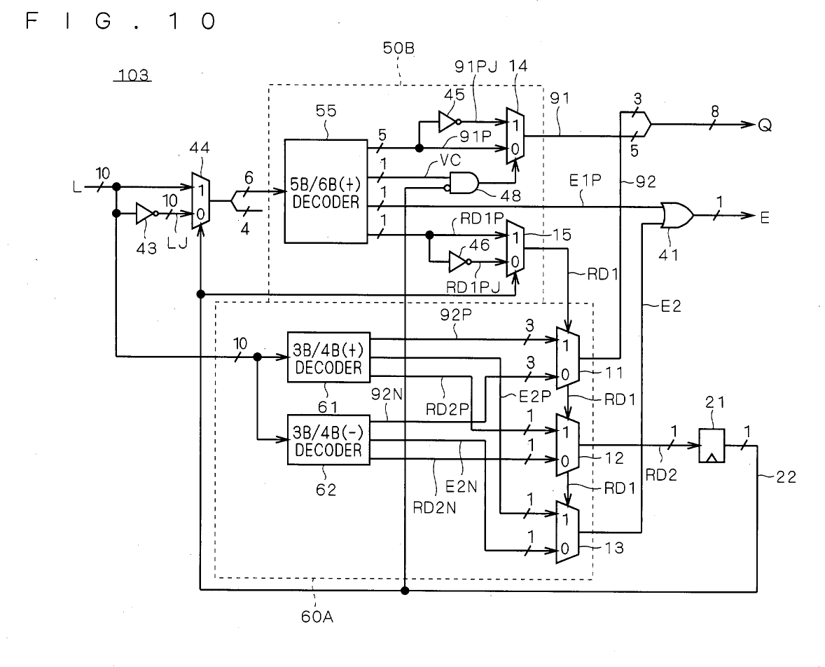

FIG. 10 is a block diagram showing the configuration of a decoding circuit 103 according to a fifth preferred embodiment of the invention. The decoding circuit 103 employs a 5B/6B decoding part 50 B as the 5B/6B decoding part 50 and a 3B/4B decoding part 60A as the 3B/4B decoding part 60. The 3B/4B decoding part 60A, to which a code group L is inputted, can handle such an exceptional case that “HGF” takes “111” in the creation of a disparity signal RD2 and error candidate signal E2, as described in the fourth preferred embodiment.

An inverter 43 inverts each bit of a code group L and then outputs an inverted code group LJ. A selector 44 outputs either one of the code group L and inverted code group LJ. If the value of a disparity signal 22 is “1”, the selector 44 outputs the code group L. If the value of the disparity signal 22 is “0”, the selector 44 outputs the inverted code group LJ. Among the outputs of the selector 44, a 6-bit subblock “abcdej” or data obtained by inverting each bit of the 6-bit subblock is inputted to the 5B/6B decoding part 50B.

The 5B/6B decoding part 50B has a 5B/6B (+) decoder 55, a 5-bit inverter 45, a 1-bit inverter 46, selectors 14 and 15, and a logic gate 48. Like the 5B/6B (+) decoder 51, the 5B/6B (+) decoder 55 stores look-up tables corresponding to the case that the current running disparity is positive in the association of 5B/6B shown in Table 2, it preferably also stores look-up tables corresponding to the case that the current running disparity is positive in the association of 5B/6B shown in Table 3. The 5B/6B (+) decoder 55 has the function of outputting an inverted correction signal VC, in addition to the function of the 5B/6B (+) decoder 51 described in the second preferred embodiment. The inverted correction signal VC will be described later. The logic gate 48 outputs a logical AND between an inverted correction signal VC and an inversion of the disparity signal 22.

The 5B/6B (+) decoder 55 outputs a decoded data candidate 91P. The inverter 45 inverts each bit of the decoded data candidate 91P and then outputs a decoded data candidate 91PJ. The decoded data candidates 91PJ and 91P are inputted to one input terminal of the selector 14 and the other input terminal, respectively. The selector 14 outputs as decoded data 91 the decoded data candidates 91PJ and 91P when the output of the logic gate 48 takes “1” and “0”, respectively.

The 5B/6B (+) decoder 55 outputs a disparity candidate signal RD1P. The inverter 46 inverts the disparity candidate signal RD1P and then outputs a disparity candidate signal RD1PJ. The disparity candidate signals RD1P and RDP1J are inputted to one input terminal of the selector 15 and the other input terminal, respectively. The selector 15 outputs as a disparity signal RD1 the disparity candidate signals RD1P and RDP1J when the disparity signal 22 takes “1” and “0”, respectively.

Like the 5B/6B (+) decoder 51, the 5B/6B (+) decoder 55 outputs a spare error candidate signal E1P.

The 3B/4B decoding part 60A has the same configuration as described in the first preferred embodiment. Because of the exceptional handling when the decoded data “HGF” takes “111”, as described above, the 3B/4B (+) decoder 61 and 3B/4B (−) decoder 62 contain the configurations shown in FIGS. 8 and 9, respectively.

Table 5 illustrates the rules in Table 2. The left column indicates the code group name of data codes. Symbols “(+)” and “(−)” represent the correspondence to the positive current running disparity and the negative current running disparity, respectively. Symbol “x” represents that the rule in Table 2 exists without depending on the value of a 4-bit subblock “fghj” of a code group. The middle column indicates a 5-bit decoded data corresponding to the code group. The right column indicates that the decoding result corresponding to the group whose name is described in the left column (i.e., the 5-bit in the middle column) can be obtained by inverting each bit of the decoding result corresponding to other code group.

TABLE 5

| Code | | |
|---|---|---|
| Group | 5B | |
| Name | Output | Contents |
| D11.x(−) | 01011 | Inversion of Decoding Result of D20.x(+) (10100) |
| D19.x(−) | 10011 | Inversion of Decoding Result of D12.x(+) (01100) |
| D3.x(−) | 00011 | Inversion of Decoding Result of D28.x(+) (11100) |
| D13.x(−) | 01101 | Inversion of Decoding Result of D18.x(+) (10010) |
| D21.x(−) | 10101 | Inversion of Decoding Result of D10.x(+) (01010) |
| D5.x(−) | 00101 | Inversion of Decoding Result of D26.x(+) (11010) |
| D25.x(−) | 11001 | Inversion of Decoding Result of D6.x(+) (00110) |
| D9.x(−) | 01001 | Inversion of Decoding Result of D22.x(+) (10110) |
| D17x(−) | 10001 | Inversion of Decoding Result of D14.x(+) (01110) |
| D14.x(−) | 01110 | Inversion of Decoding Result of D17.x(+) (10001) |
| D22.x(−) | 10110 | Inversion of Decoding Result of D9.x(+) (01001) |
| D6.x(−) | 00110 | Inversion of Decoding Result of D25.x(+) (11001) |
| D26.x(−) | 11010 | Inversion of Decoding Result of D5.x(+) (00101) |
| D10.x(−) | 01010 | Inversion of Decoding Result of D21.x(+) (10101) |
| D18.x(−) | 10010 | Inversion of Decoding Result of D13.x(+) (01101) |
| D28x(−) | 11100 | Inversion of Decoding Result of D3.x(+) (00011) |
| D12.x(−) | 01100 | Inversion of Decoding Result of D19.x(+) (10011) |
| D20.x(−) | 10100 | Inversion of Decoding Result of D11.x(+) (01011) |

Consider now the case that when the current running disparity is negative, a 6-bit subblock “abcdei” is obtained as “110100”. This case corresponds to code group D11.x(−) described in the uppermost row in the left column of Table 5. The value obtained by inverting each bit of the 6-bit subblock “abcdei” is “001011”. This corresponds to code group D20.x(+) when the current running disparity is positive, and is described in the same row of the right column. If a subblock “abcdei” corresponds to a subblock whose name is described in the left column in Table 5, the name of a 6-bit data obtained by inverting each bit of this subblock (hereinafter referred to as an “inverted subblock”) is also described in the left column of Table 5.

The decoded data “10100” is obtainable by decoding the code group D20.x(+) in accordance with the look-up table for positive current running disparity, i.e., the look-up table stored in the 5B/6B (+) decoder 55. Then, inverting each bit of this result produces the normal decoded data “01011” as in the case that the 6-bit subblock “abcdei” is obtained as “110100” when the current running disparity is negative.

On the other hand, code groups other than the code groups of which name is described in the left column of Table 5 have the following rule. That is, the normal decoding is possible by executing decoding in accordance with the look-up table stored in the 5B/6B (+) decoder 55, by using the 6-bit subblock “abcdei” when the current running disparity is positive or the inverted subblock when the current running disparity is negative.

From the foregoing, to the 5B/6B (+) decoder 55, the 6-bit subblock and inverted subblock are provided when the current running disparity is positive and negative, respectively. Concretely, since the look-up table for positive current running disparity is stored in the 5B/6B (+) decoder 55, the output of the selector 44 is provided to the 5B/6B (+) decoder 55. The inverted correction signal VC takes “1” when the 6-bit subblock corresponding to a code group of which name is described in the left column of Table 5 is provided to the 5B/6B (+) decoder 55, and it takes “0” in other cases. That is, the inverted correction signal VC is activated when the subblock or inverted subblock provided to the 5B/6B (+) decoder 55 takes a predetermined value corresponding to a code group whose name is described in Table 5.

Firstly, the case where the current running disparity is positive will be described. In this case, a subblock “abcdei” is provided to the 5B/6B (+) decoder 55. Then, the output of the logic gate 48 becomes “0”, regardless of whether or not this subblock is a subblock whose name is described in the left column of Table 5, that is, irrespective of the value of the inverted correction signal VC. This is because the disparity signal 22 is “1”. Therefore, when the current running disparity is positive, the subblock “abcdei” can be decoded normally and the disparity signal RD1 can be obtained validly. It is therefore possible to obtain validly the disparity signal RD2 that the 3B/4B decoding part 60A outputs.

Following is the case where the current running disparity is negative. In this case, an inverted subblock is provided to the 5B/6B (+) decoder 55. Further, if the subblock “abcdei” corresponds to a subblock whose name is described in the left column of Table 5, the inverted subblock to be inputted to the 5B/6B (+) decoder 55 agrees with a subblock whose name is correspondingly described in the right column of Table 5. For example, a subblock “10100” is provided to the selector 44, an inverted subblock “001011” is provided to the 5B/6B (+) decoder 55. Therefore, the normal decoding as mentioned above can be executed by decoding in accordance with the look-up table stored in the 5B/6B (+) decoder 55 with the use of this inverted subblock, and then inverting the obtained decoding result.

Since the current running disparity is negative and the disparity signal 22 is “0”, the output of the logic gate 48 agrees with the value of the inverted correction signal VC. As described above, when the subblock “abcdei” corresponds to a subblock whose name is described in the left column of Table 5, the name of the inverted subblock is also described in the left column of Table 5, so that the inverted correction signal VC takes “1” and the output of the logic gate 48 is also “1”. As the result, the decoded data candidate 91PJ, which is obtained by inverting in the inverter 45 the result of decoding in accordance with the look-up table stored in the 5B/6B (+) decoder 55, is outputted from the selector 14 as decoded data 91, thus performing the normal decoding.

Following is the case that the current running disparity is negative and a subblock “abcdei” does not correspond to any subblock whose name is described in the left column of Table 5. In this case, the inverted correction signal VC takes “0”, and the output of the logic gate 48 becomes “0”. As the result, the decoded data candidate 91P, which is the result of decoding in accordance with the look-up table stored in the 5B/6B (+) decoder 55, is outputted as decoded data 91, thus performing the normal decoding.

It is necessary to invert the value of a disparity signal RD1 because when the current running disparity is negative, the running disparity of a 6-bit subblock is calculated based on an inverted subblock. Then, the selector 15 outputs the disparity candidate signal RD1PJ as a disparity signal RD1, based on the fact that the disparity signal 22 indicating the current running disparity is “0”.

In the fifth preferred embodiment, the look-up tables stored in the 3B/4B (+) decoder 61 and 5B/6B (+) decoder 55 are only required to correspond to the case where the current running disparity is positive. This permits to reduce the sizes of the look-up tables and also reduce the time required to search for the tables, thereby achieving a quick decoding in units of code groups. In addition, the decoding from the subblock “fghj” and part of the creation of the disparity signal RD2 and error candidate signal E2 can be executed without waiting for obtaining the disparity signal RD1. Therefore, these operations can be executed in parallel with the decoding from the subblock “abcdei” and the creation of current running disparity, thereby achieving a quick decoding in units of code groups.

### Sixth Preferred Embodiment

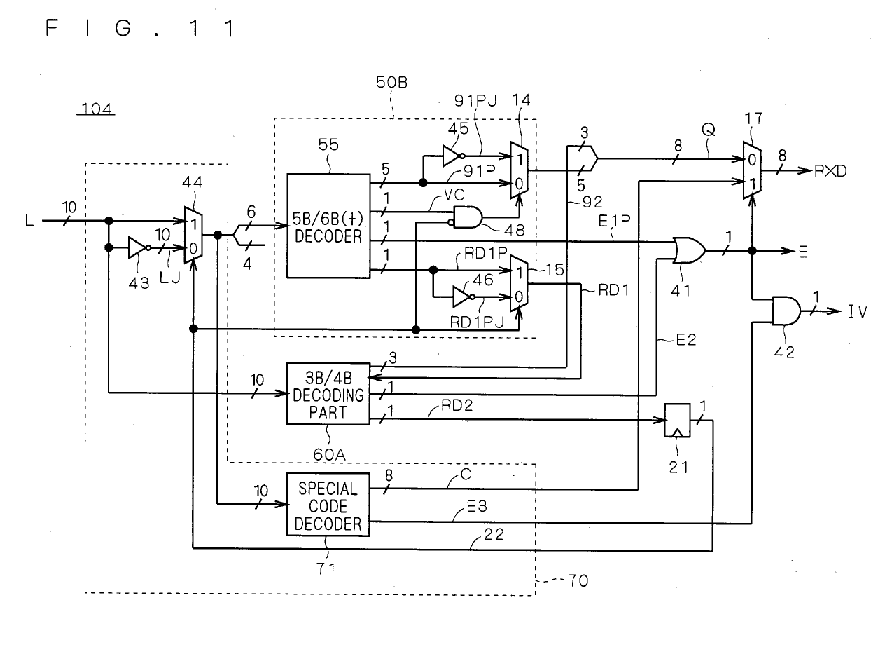

FIG. 11 is a block diagram showing the configuration of a decoding circuit 104 according to a sixth preferred embodiment. The decoding circuit 104, which is obtained by adding the special code decoding part 70, logic gate 42, and selector 17 in the decoding circuit 102 into the decoding circuit 103, requires that the look-up tables about special codes be stored in the special code decoder 71 and that the 5B/6B (+) decoder 55 and 3B/4B decoding part 60A store only the look-up tables about data codes, as in the decoding circuit 102.

The inverter 43 and selector 44 are contained in the decoding circuit 103, and they also perform the functions of the inverter 43 and selector 18, respectively, which are contained in the special code decoding part 70 of the decoding circuit 102. In order to obtain the decoding circuit 104 by adding the special code decoding part 70 to the decoding circuit 103, it is only required to add the special code decoder 71.

According to the sixth preferred embodiment, the effect of the fifth preferred embodiment is obtainable, and the decoding circuit 104 as a whole can decode special codes even if the 5B/6B decoding part 50 B and 3B/4B decoding part 60A have look-up tables only about data codes.

In some cases, only the function of detecting invalidness of the code group L and disparity signal 22 is required. On this occasion, the function of obtaining the decoded data Q and C is unnecessary and no look-up table is required to store decoded data, permitting a reduction in the size of the look-up table. In addition, the 5B/6B (+) decoding part 50 B does not require any one of the logic gate 48, inverter 45, selector 14, and selector 17. The 3B/4B decoding part 60A also does not require the selector 11 (see FIG. 10).

### Modifications

The fifth and sixth preferred embodiments have presented the examples of omitting the look-up table for negative current running disparity. A modified configuration of omitting the look-up table for positive current running disparity is of course in the scope of the present invention. For example, a 5B/6B (−) decoder storing the look-up table for negative current running disparity may be used in place of the 5B/6B (+) decoder 55.

The third and sixth preferred embodiments have presented the examples that the special code decoder 71 has the look-up tables only for positive or negative current running disparity among those shown in Tables 3 and 4, by selectively providing the code group L and inverted code group LJ to the special code decoder 71, depending on the value of the disparity signal 22.

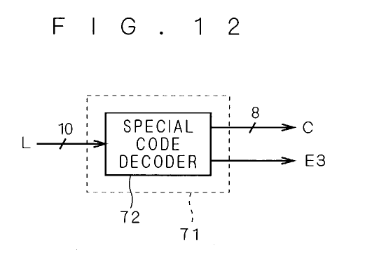

In an alternative, special code decoding may be executed by using look-up tables covering both of the positive and negative current running disparity. FIG. 12 shows an example that the special code decoding part 70 is configured by a special code decoder 72 having these look-up tables. In this example, the inverter 43 and selector 18 shown in FIG. 4 are unnecessary and there is no need to receive the disparity signal 22. It is easy to apply the special code decoder 72 to the decoding circuit 102 (FIG. 4) in the third preferred embodiment.

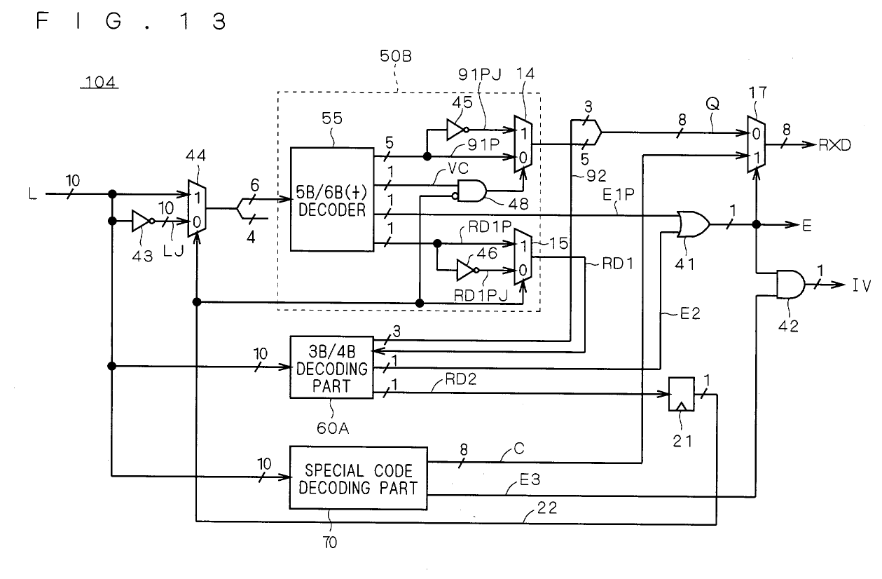

FIG. 13 is a circuit diagram showing an example of applying the special code decoder 72 to the decoding circuit 104 (FIG. 11) in the sixth preferred embodiment. Unlike the operation described in the sixth preferred embodiment, the inverter 43 and selector 44 do not function in the special code decoding part 70.

While the invention has been shown and described in detail, the foregoing description is in all aspects illustrative and not restrictive. It is therefore understood that numerous modifications and variations can be devised without departing from the scope of the invention.

What is claimed is:

1. A detection circuit for detecting invalidness of a code group composed of first and second subblocks, said detection circuit comprising:
a first processing part for obtaining a first running disparity about said first subblock; and
a second processing part for obtaining a second running disparity about said second subblock, based on said first running disparity,
at least part of the operation for obtaining said second running disparity being performed in parallel with the operation for obtaining said first running disparity.

2. The detection circuit according to claim 1 further comprising a delay element for delaying data by one clock, wherein
said first processing part obtains, based on said first block of said code group of a succeeding period and said second running disparity of said code group of a preceding period prior to said code group of said succeeding period, said first running disparity about said code group of the succeeding period,
said second processing part obtains, based on said first running disparity of said code group of said succeeding period and said second subblock of said code group of said succeeding period, said second running disparity about said second subblock of said code group of said succeeding period, and
said delay element delays said second running disparity by one clock and then outputs the result to said first processing part.

3. The detection circuit according to claim 2 wherein
said second processing part obtains (i) a first running disparity candidate equivalent to said second running disparity when said first running disparity is positive and (ii) a second running disparity candidate equivalent to said second running disparity when said first running disparity is negative, then selects and outputs as said second running disparity either one of said first and second running disparity candidates based on the polarity of said first running disparity.

4. The detection circuit according to claim 3 wherein
said first processing part obtains (i) a third running disparity candidate equivalent to said first running disparity when said second running disparity is positive and (ii) a fourth running disparity candidate equivalent to said first running disparity when said second running disparity is negative, then selects and outputs as said first running disparity either one of said third and fourth running disparity candidates based on the polarity of said second running disparity.

5. The detection circuit according to claim 3 wherein
based on said second running disparity, either one of said code group and an inverted code group obtained by inverting each bit of said code group is selected and provided as an input to said first processing part,
said first processing part obtains, based on said input, a third running disparity candidate equivalent to said first running disparity when said second running disparity takes a first sign that is either one of positive and negative, then employs as said first running disparity (i) said third running disparity candidate when said second running disparity takes said first sign and (ii) a sign opposite that of said third running disparity candidate when said second running disparity takes a second sign opposite said first sign.

6. The detection circuit according to claim 1 wherein
said first processing part outputs a first error candidate signal activated when said first subblock takes a value that cannot be taken in the normal operation, and
said second processing part outputs a second error candidate signal activated when said second subblock takes a value that cannot be taken in the normal operation,
said detection circuit outputs an error signal activated when at least either one or both of said first and second error candidate signals is activated.

7. The detection circuit according to claim 6 wherein either one of a data code and special code is encoded in said code group, further comprising:
a third processing part outputting a third error candidate signal activated when said special code in said code group is not encoded,
said detection circuit outputs an invalid signal indicating whether both of said error signal and said third error candidate signal are activated.

8. The detection circuit according to claim 7 wherein
said third processing part obtains an inverted code group that is data obtained by inverting each bit of said code group and judges whether said special code is encoded about either one of said code group and said inverted code group selected based on said second running disparity.

9. A decoding circuit for decoding a code group composed of first and second subblocks, said decoding circuit comprising:
a first decoding part for obtaining a first running disparity and a first decoded data about said first subblock; and
a second decoding part for obtaining a second running disparity and a second decoded data about said second subblock, based on said first running disparity,
at least part of the operation for obtaining said second decoded data being performed in parallel with the operation for obtaining said first running disparity.

10. The decoding circuit according to claim 9 further comprising a delay element for delaying data by one clock, wherein
said first decoding part obtains, based on said first subblock of said code group of a succeeding period and said second running disparity of said code group of a preceding period prior to said code group of said succeeding period, said first running disparity about said code group of said succeeding period,
said second decoding part obtains, based on said first running disparity of said code group of said succeeding period and said second subblock of said code group of said succeeding period, said second running disparity about said second subblock of said code group of said succeeding period, and
said delay element delays said second running disparity by one clock and then outputs the result to said first decoding part.

11. The decoding circuit according to claim 10 wherein
said second decoding part obtains a first decoded data candidate equivalent to said second decoded data when said first running disparity is positive and a second decoded data candidate equivalent to said second decoded data when said first running disparity is negative, then selects and outputs as said second decoded data either one of said first and second decoded data candidates based on the polarity of said first running disparity.

12. The decoding circuit according to claim 11 wherein
said first decoding part obtains a third decoded data candidate equivalent to said first decoded data when said second running disparity is positive and a fourth decoded data candidate equivalent to said first decoded data when said second running disparity is negative, then selects and outputs as said first decoded data either one of said third and fourth decoded data candidates based on the polarity of said second running disparity.

13. The decoding circuit according to claim 10 wherein
said code group and an inverted code group obtained by inverting each bit of said code group are provided respectively when said second running disparity takes a first sing that is either one of positive and negative and when said second running disparity takes a second sign that is opposite said first sign, as an input to said first decoding part,
said first decoding part obtains a first decoded data candidate equivalent to said first decoded data when said second running disparity takes said first sign, based on said input, employs said first decoded data candidate as said first decoded data when said second running displarit takes said first sign, and
when said second running disparity takes said second sign and said input has a predetermined value, said first decoding part employs as said first decoded data a second decoded data candidate obtained by inverting each bit of said first decoded data candidate.

14. The decoding circuit according to claim 9 wherein either one of a data code and special code is encoded in said code group, further comprising:
a third decoding part that outputs a third decoded data based on the association between said code group and said special code, wherein
said first decoding part outputs said first decoded data based on the association between said first subblock and said data code, and outputs a first error candidate signal activated when said first subblock takes a value that cannot be taken as said data code, and
said second decoding part outputs said second decoded data based on the association between said second subblock and said data code, and outputs a second error candidate signal activated when said second subblock takes a value that cannot be taken as said data code,
said decoding circuit outputs said third decoded data when at least either one or both of said first and second error candidate signals is activated and outputs said first and second decoded data in other cases.
